(19) United States
(12) Patent Application Publication
(10) Pub. No.: US 2015/0173232 A1
(43) Pub. Date: Jun. 18, 2015

(54) DISPLAY PANEL AND FAN OUT-LINE STRUCTURE THEREOF

(71) Applicant: Li Chai, Shenzhen City (CN)

(72) Inventor: Li Chai, Shenzhen City (CN)

(73) Assignee: Shenzhen China Star Optoelectronics Technology Co., Ltd., Shenzhenn, Guangdong (CN)

(21) Appl. No.: 14/232,281

(22) PCT Filed: Aug. 12, 2013
(86) PCT No.: PCT/CN2013/081277

§ 371 Date: Jan. 12, 2014

(30) Foreign Application Priority Data
Aug. 1, 2013 (CN) 201310332269.5

(51) Int. Cl. H05K 7/06

(52) U.S. Cl. CPC H05K 7/06

(57) ABSTRACT

A fan out-line structure of a display panel is disclosed. The display panel comprises a display area and a bonding area. The display area includes a plurality of signal lines, and the bonding area comprises a pad. The fan out-line structure includes a plurality of fan out-lines arranged between the display area and the bonding area. The fan-out line is a conductive line with double-layer structure having a first conductive layer and a second conductive layer. Projections of the first conductive layer and the second conductive layer arranged in the middle section are at least partially interleaved with each other on a plane of the display panel. With such configuration, the electrostatic risk between two conductive layers of the fan out-line structure is reduced so as to enhance the yield rate and reduce the cost.

### BACKGROUND OF THE INVENTION

1. Field of the Invention

The present disclosure relates to display technology, and more particularly to a display panel and the fan out-line structure thereof.

2. Discussion of the Related Art

With the advanced technology, users demand toward display devices grows such that liquid crystal (LC) display panels have evolved rapidly. The objectives of the LC display panel include reducing the cost, and improving yield rate and display performance.

The LC display panel includes a display area and a bonding area. The display area includes a plurality of signal lines, and the bonding area includes a pad. The fan out-line structure is arranged between the display area and the bonding area. The fan out-line structure connects between the pad and the signal lines. The fan out-line structure may be single-layer or double-layer. Conventional double-layer structure includes two fully overlapped conductive layers such that the electrostatic effect may occur between the two conductive layers in the manufacturing process. Even more, electrical breakdown may occur. Thus, the yield rate may be reduced, which results in damage.

Therefore, a display panel and the fan out-line structure thereof which can overcome the above problems are needed.

### SUMMARY

The object of the invention is to provide a display panel and the fan out-line structure thereof to reduce the electrostatic risk between two conductive layers of the fan out-line structure. In this way, the yield rate can be increased so as to reduce the cost.

In one aspect, a fan out-line structure of a display panel includes a display area and a bonding area, the display area includes a plurality of signal lines, the bonding area includes a pad, the fan out-line structure includes a plurality of fan out-lines arranged between the display area and the bonding area, first ends of the fan out-lines connects to the pad, and second ends of the fan out-lines connect to the signal lines, the fan-out line further includes a middle section between the first end and the second end, the fan-out line is a conductive line with double-layer structure comprising a first conductive layer and a second conductive layer, projections of the first conductive layer and the second conductive layer arranged in the middle section are at least partially interleaved with each other on a plane of the display panel, the projections of the first conductive layer and the second conductive layer arranged at the first end and the second end are at least partially interleaved with each other on the plane of the display panel, the first conductive layer is arranged below the second conductive layer, the double-layer structure further includes an insulation layer and a passivation layer, the insulation layer is arranged between the first conductive layer and the second conductive layer, and the passivation layer is arranged above the second conductive layer and the insulation layer.

Wherein the fan-out lines are lines, curves, or a combination of lines and curves, and a resistance of the fan-out lines are substantially the same.

In another aspect, a fan out-line structure of a display panel includes: the display panel includes a display area and a bonding area, the display area includes a plurality of signal lines, the bonding area includes a pad, the fan out-line structure includes a plurality of fan out-lines arranged between the display area and the bonding area, first ends of the fan out-lines connects to the pad, and second ends of the fan out-lines connect to the signal lines, the fan-out line further includes a middle section between the first end and the second end, the fan-out line is a conductive line with double-layer structure comprising a first conductive layer and a second conductive layer, and projections of the first conductive layer and the second conductive layer arranged in the middle section are at least partially interleaved with each other on a plane of the display panel.

Wherein the first conductive layer is arranged below the second conductive layer, the double-layer structure further includes an insulation layer and a passivation layer, the insulation layer is arranged between the first conductive layer and the second conductive layer, and the passivation layer is arranged above the second conductive layer and the insulation layer.

Wherein the projections of the first conductive layer and the second conductive layer arranged in the middle section are fully interleaved with each other on the plane of the display panel.

Wherein the projections of the first conductive layer and the second conductive layer arranged in the middle section are at least partially interleaved with each other on a plane of the display panel.

Wherein the first conductive layer and the second conductive layer are metallic layers.

Wherein the first conductive layer is a metallic layer and the second conductive layer is an Indium Tin Oxide (ITO) film, or the first conductive layer is the ITO film and the second conductive layer is the metallic layer.

Wherein the first conductive layer and the second conductive layer are ITO films.

Wherein the projections of the first conductive layer and the second conductive layer arranged at the first end and the second end are at least partially interleaved with each other on the plane of the display panel.

Wherein the fan-out lines are lines, curves, or a combination of lines and curves, and a resistance of the fan-out lines are substantially the same.

In another aspect, a display panel includes: a display area and a bonding area, the display area includes a plurality of signal lines, the bonding area includes a pad, the fan out-line structure includes a plurality of fan out-lines arranged between the display area and the bonding area, first ends of the fan out-lines connects to the pad, and second ends of the fan out-lines connect to the signal lines, the fan-out line further includes a middle section between the first end and the second end, the fan-out line is a conductive line with double-layer structure comprising a first conductive layer and a second conductive layer, and projections of the first conductive layer and the second conductive layer arranged in the middle section are at least partially interleaved with each other on a plane of the display panel.

Wherein the first conductive layer is arranged below the second conductive layer, the double-layer structure further includes an insulation layer and a passivation layer, the insulation layer is arranged between the first conductive layer and the second conductive layer, and the passivation layer is arranged above the second conductive layer and the insulation layer.

Wherein the first conductive layer is arranged below the second conductive layer, the double-layer structure further includes an insulation layer and a passivation layer, the insulation layer is arranged between the first conductive layer and the second conductive layer, and the passivation layer is arranged above the second conductive layer and the insulation layer.

Wherein the projections of the first conductive layer and the second conductive layer arranged in the middle section are at least partially interleaved with each other on the plane of the display panel.

Wherein the first conductive layer and the second conductive layer are metallic layers.

Wherein the first conductive layer is a metallic layer and the second conductive layer is an ITO film, or the first conductive layer is the ITO film and the second conductive layer is the metallic layer.

Wherein the first conductive layer and the second conductive layer are ITO films.

Wherein the projections of the first conductive layer and the second conductive layer arranged at the first end and the second end are at least partially interleaved with each other on the plane of the display panel.

Wherein the fan-out lines are lines, curves, or a combination of lines and curves, and a resistance of the fan-out lines are substantially the same.

Comparing to the conventional technology, by arranging the projections of the first conductive layer and the second conductive layer to be at least partially interleaved with each other, the electrostatic risk between the two conductive layers of the fan-out lines can be reduced. In this way, the yield rate can be increased so as to reduce the cost.

### BRIEF DESCRIPTION OF THE DRAWINGS

FIG. 1 is a schematic view of the display panel in accordance with one embodiment.

FIG. 2 is a schematic view showing the projections of the first conductive layer and the second conductive layer of the fan out-line structure on the plane of the display panel in accordance with one embodiment.

FIG. 3 is a cross section view of the fan out-line structure along the “A-A” line of FIG. 2 in accordance with a first embodiment.

FIG. 4 is a cross section view of the fan out-line structure along the “B-B” line of FIG. 2 in accordance with a first embodiment.

FIG. 5 is a cross section view of the fan out-line structure along the “C-C” line of FIG. 2 in accordance with a first embodiment.

FIG. 6 is a schematic view showing the projections of the first conductive layer and the second conductive layer of the fan out-line structure on the plane of the display panel in accordance with a second embodiment.

FIG. 7 is a cross section view of the fan out-line structure along the “D-D” line of FIG. 6 in accordance with a second embodiment.

### DETAILED DESCRIPTION OF THE EMBODIMENTS

Embodiments of the invention will now be described more fully hereinafter with reference to the accompanying drawings, in which embodiments of the invention are shown.

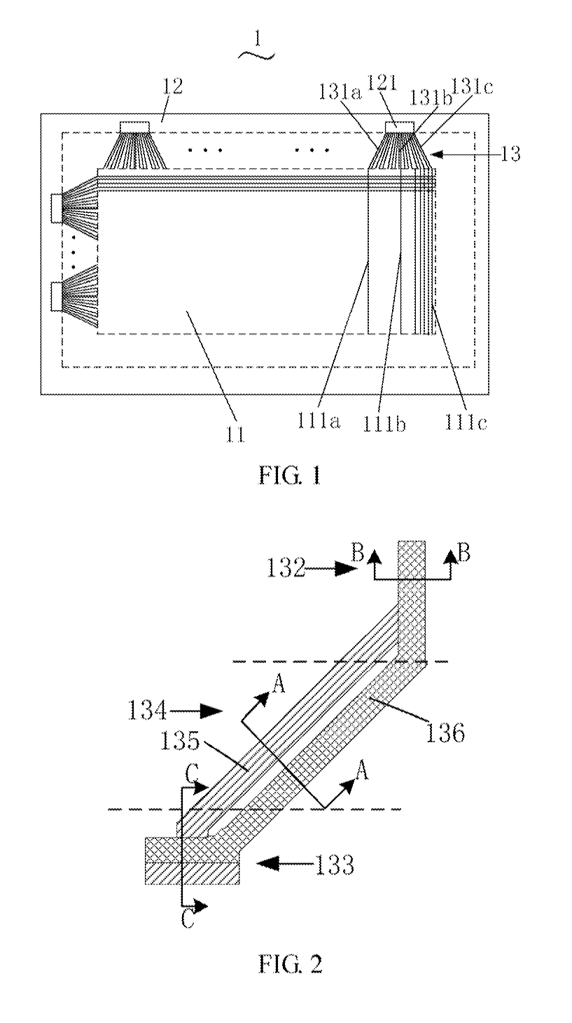

FIG. 1 is a schematic view of the display panel in accordance with one embodiment. The display panel 1 includes a display area 11 and a bonding area 12.

The display area 11 includes a plurality of signal lines 111a, 111b, 111c. The bonding area 12 includes a pad 121.

A fan out-line structure 13 includes a plurality of fan-out lines 131a, 131b, 131c. First ends of the fan-out lines 131a, 131b, 131c connect to the pad 121, and second ends of the fan-out lines 131a, 131b, 131c connects to the signal lines 111a, 111b, 111c. For example, the signal lines may be scanning signal lines or data signals lines. The fan-out lines 131a, 131b, 131c may be lines, curves, or a combination of lines and curves. In addition, the resistance of the fan-out lines 131a, 131b, 131c are substantially the same.

Each of the fan-out lines 131a, 131b, 131c are conductive lines with double layers including a first conductive layer and a second conductive layer. FIG. 2 is a schematic view showing the projections of the first conductive layer and the second conductive layer of the fan out-line structure on the plane of the display panel in accordance with one embodiment. In the embodiment, the fan-out lines 131a includes a first end 132, a second end 133 and a middle section 134 between the first end 132 and the second end 133. The fan-out line 131a is one conductive line with double-layer structure including the first conductive layer 135 and the second conductive layer 136.

The projections of the first conductive layer 135 and the second conductive layer 136 arranged in the middle section 134 are at least partially interleaved with each other on a plane of the display panel 1. In the embodiment, the projections of the first conductive layer 135 and the second conductive layer 136 in the middle section 134 are fully interleaved with each other on the plane of the display panel 1.

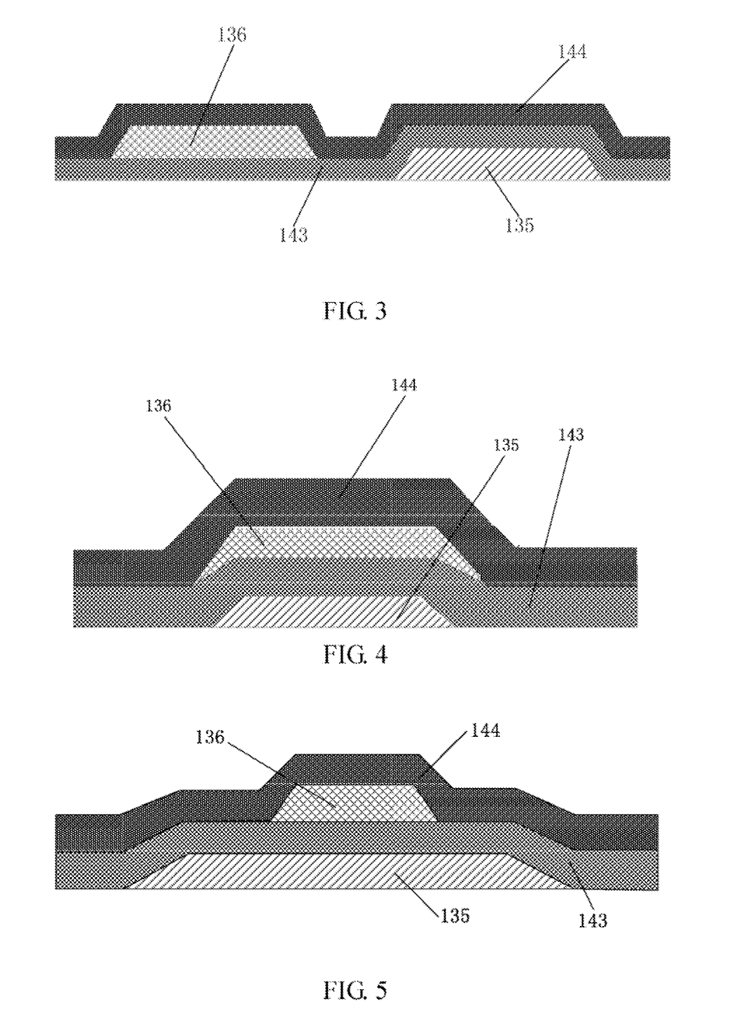

FIG. 3 is a cross section view of the fan out-line structure along the “A-A” line of FIG. 2 in accordance with a first embodiment. The first conductive layer 135 is arranged below the second conductive layer 136. The double-layer structure further includes an insulation layer 143 and a passivation layer 144. The insulation layer 143 is arranged between the first conductive layer 135 and the second conductive layer 136. The passivation layer 144 is arranged above the second conductive layer 136 and the insulation layer 143. In one embodiment, the projections of the first conductive layer 135 and the second conductive layer 136 are interleaved with each other along a width direction of the first conductive layer 135 on the plane of the display panel 1.

FIG. 4 is a cross section view of the fan out-line structure along the “B-B” line of FIG. 2 in accordance with a first embodiment. The first conductive layer 135 and the second conductive layer 136 arranged at the furthest end of the first end 132 are fully overlapped with each other so as to decrease a span between the furthest ends of the first conductive layer 135 and the second conductive layer 136 in the manufacturing process of the display panel 1. As such, the connection resistance is reduced.

As shown in FIG. 4, the farthest end of the first end 132 of the second conductive layer 136, as indicated by “B-B” line, is arrange above the first conductive layer 135. The insulation layer 143 is arranged between the first conductive layer 135 and the second conductive layer 136. The passivation layer 144 is arranged above the second conductive layer 136 and the insulation layer 143. In other embodiments, the projections of the first conductive layer 135 and the second conductive layer 136 arranged at the first end 132 and the second end 133 may be partially or fully interleaved with each other on the plane of the display panel 1.

FIG. 5 is a cross section view of the fan out-line structure along the “C-C” line of FIG. 2 in accordance with a first embodiment. The projections of the first conductive layer 135 and the second conductive layer 136 arranged at the second end 133 are partially interleaved with each other on the plane of the display panel 1. The configuration is similar to the first end 132.

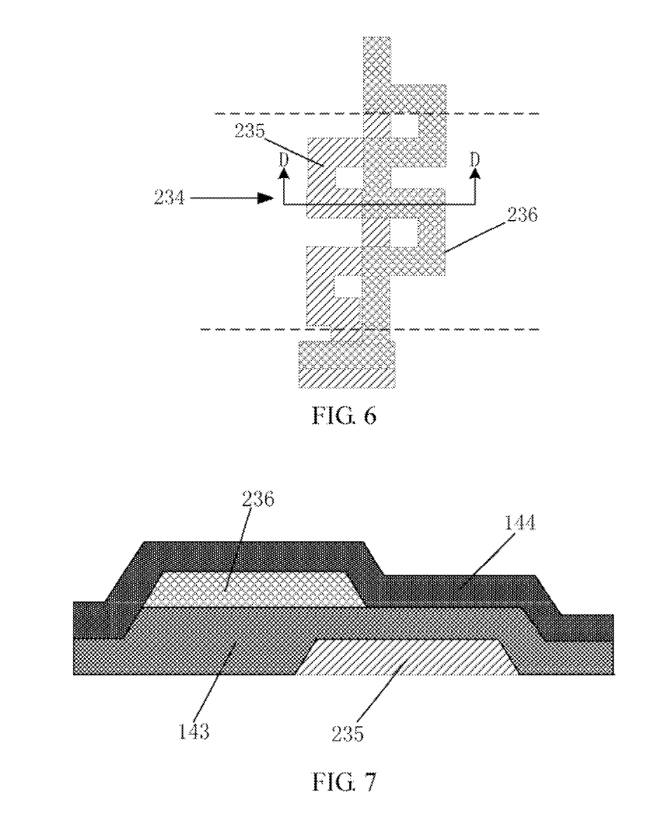

FIG. 6 is a schematic view showing the projections of the first conductive layer and the second conductive layer of the fan out-line structure on the plane of the display panel in accordance with a second embodiment. In the embodiment, the projections of the first conductive layer 235 and the second conductive layer 236 arranged in the middle section 234 are partially interleaved with each other.

FIG. 7 is a cross section view of the fan out-line structure along the “D-D” line of FIG. 6 in accordance with a second embodiment. In this embodiment, the second conductive layer 236 arranged in the location indicated by “D-D” line is arranged laterally over the first conductive layer 235.

It is to be noted that in any of the above embodiments, the first conductive layer 135, 235 and the second conductive layer 136, 236 are metallic layers. Alternatively, the first conductive layer 135, 235 are metallic layers and the second conductive layer 136, 236 are Indium Tin Oxide (ITO) films. Alternatively, the first conductive layer 135, 235 are ITO films and the second conductive layer 136, 236 are metallic layers. Alternatively, the first conductive layer 135, 235 and the second conductive layer 136, 236 are ITO films.

It can be understood that the technical features disclosed in the above embodiments can be re-configured to form a new embodiment.

Comparing to the conventional technology, by arranging the projections of the first conductive layer and the second conductive layer to be at least partially interleaved with each other, the electrostatic risk between the two conductive layers of the fan-out lines can be reduced. In this way, the yield rate can be increased so as to reduce the cost.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A fan out-line structure of a display panel, comprising:
the display panel comprises a display area and a bonding area, the display area comprises a plurality of signal lines, the bonding area comprises a pad, the fan out-line structure comprises a plurality of fan out-lines arranged between the display area and the bonding area, first ends of the fan out-lines connects to the pad, and second ends of the fan out-lines connect to the signal lines, the fan-out line further comprises a middle section between the first end and the second end, the fan-out line is a conductive line with double-layer structure comprising a first conductive layer and a second conductive layer, projections of the first conductive layer and the second conductive layer arranged in the middle section are at least partially interleaved with each other on a plane of the display panel, the projections of the first conductive layer and the second conductive layer arranged at the first end and the second end are at least partially interleaved with each other on the plane of the display panel, the first conductive layer is arranged below the second conductive layer, the double-layer structure further comprises an insulation layer and a passivation layer, the insulation layer is arranged between the first conductive layer and the second conductive layer, and the passivation layer is arranged above the second conductive layer and the insulation layer.

2. The fan-out line structure as claimed in claim 1, wherein the fan-out lines are lines, curves, or a combination of lines and curves, and a resistance of the fan-out lines are substantially the same.

3. A fan out-line structure of a display panel, comprising:
the display panel comprises a display area and a bonding area, the display area comprises a plurality of signal lines, the bonding area comprises a pad, the fan out-line structure comprises a plurality of fan out-lines arranged between the display area and the bonding area, first ends of the fan out-lines connects to the pad, and second ends of the fan out-lines connect to the signal lines, the fan-out line further comprises a middle section between the first end and the second end, the fan-out line is a conductive line with double-layer structure comprising a first conductive layer and a second conductive layer, and projections of the first conductive layer and the second conductive layer arranged in the middle section are at least partially interleaved with each other on a plane of the display panel.

4. The fan-out line structure as claimed in claim 3, wherein the first conductive layer is arranged below the second conductive layer, the double-layer structure further comprises an insulation layer and a passivation layer, the insulation layer is arranged between the first conductive layer and the second conductive layer, and the passivation layer is arranged above the second conductive layer and the insulation layer.

5. The fan-out line structure as claimed in claim 4, wherein the projections of the first conductive layer and the second conductive layer arranged in the middle section are fully interleaved with each other on the plane of the display panel.

6. The fan-out line structure as claimed in claim 4, wherein the projections of the first conductive layer and the second conductive layer arranged in the middle section are at least partially interleaved with each other on a plane of the display panel.

7. The fan-out line structure as claimed in claim 4, wherein the first conductive layer and the second conductive layer are metallic layers.

8. The fan-out line structure as claimed in claim 4, wherein the first conductive layer is a metallic layer and the second conductive layer is an Indium Tin Oxide (ITO) film, or the first conductive layer is the ITO film and the second conductive layer is the metallic layer.

9. The fan-out line structure as claimed in claim 4, wherein the first conductive layer and the second conductive layer are ITO films.

10. The fan-out line structure as claimed in claim 3, wherein the projections of the first conductive layer and the second conductive layer arranged at the first end and the second end are at least partially interleaved with each other on the plane of the display panel.

11. The fan-out line structure as claimed in claim 3, wherein the fan-out lines are lines, curves, or a combination of lines and curves, and a resistance of the fan-out lines are substantially the same.

12. A display panel, comprising:
a display area and a bonding area, the display area comprises a plurality of signal lines, the bonding area comprises a pad, the fan out-line structure comprises a plurality of fan out-lines arranged between the display area and the bonding area, first ends of the fan out-lines connects to the pad, and second ends of the fan out-lines connect to the signal lines, the fan-out line further comprises a middle section between the first end and the second end, the fan-out line is a conductive line with double-layer structure comprising a first conductive layer and a second conductive layer, and projections of the first conductive layer and the second conductive layer arranged in the middle section are at least partially interleaved with each other on a plane of the display panel.

13. The display panel as claimed in claim 12, wherein the first conductive layer is arranged below the second conductive layer, die double-layer structure further comprises an insulation layer and a passivation layer, the insulation layer is arranged between the first conductive layer and the second conductive layer, and the passivation layer is arranged above the second conductive layer and the insulation layer.

14. The display panel as claimed in claim 13, wherein the first conductive layer is arranged below the second conductive layer, the double-layer structure further comprises an insulation layer and a passivation layer, the insulation layer is arranged between the first conductive layer and the second conductive layer, and the passivation layer is arranged above the second conductive layer and the insulation layer.

15. The display panel as claimed in claim 13, wherein the projections of the first conductive layer and the second conductive layer arranged in the middle section are at least partially interleaved with each other on the plane of the display panel.

16. The display panel as claimed in claim 13, wherein the first conductive layer and the second conductive layer are metallic layers.

17. The display panel as claimed in claim 13, wherein the first conductive layer is a metallic layer and the second conductive layer is an ITO film, or the first conductive layer is the ITO film and the second conductive layer is the metallic layer.

18. The display panel as claimed in claim 13, wherein the first conductive layer and the second conductive layer are ITO films.

19. The display panel as claimed in claim 12, wherein the projections of the first conductive layer and the second conductive layer arranged at the first end and the second end are at least partially interleaved with each other on the plane of the display panel.

20. The display panel as claimed in claim 12, wherein the fan-out lines are lines, curves, or a combination of lines and curves, and a resistance of the fan-out lines are substantially the same.
